(19) United States
(12) Patent Application Publication
(10) Pub. No.: US 2026/0305355 A1
(43) Pub. Date: Oct. 1, 2026

(54) CIRCUIT PACKAGE STRUCTURE WITH A CONDUCTIVE PILLAR AND RELATED CONDUCTIVE PILLAR

(71) Applicant: Chengdu Monolithic Power Systems Co., Ltd., Chengdu (CN)

(72) Inventors: YanXin Wang, Chengdu (CN); Xingguo Liu, Chengdu (CN); Zhiqi Wang, Chengdu (CN); Shenglin Zhang, Chengdu (CN); Zheng Nie, Chengdu (CN); Haifeng Li, Chengdu (CN)

(21) Appl. No.: 19/634,281

(22) Filed: Mar. 31, 2026

(30) Foreign Application Priority Data
Mar. 31, 2025 (CN) 202510397547.8

(51) Int. Cl. H10W 42/00; H01F 27/24; H01F 27/28; H10W 72/00; H10W 74/00

(52) U.S. Cl. CPC H10W 42/121; H01F 27/24; H01F 27/2804; H10W 72/823; H10W 74/00

(57) ABSTRACT

This application discloses a circuit package structure with a conductive pillar. The circuit package structure includes a device layer and an inductive element layer. The conductive pillar provided in the device layer are coupled to the inductive element layer. The side wall of the conductive pillar is provided with cavity for accommodating encapsulating material, and the encapsulating material fills the space within the cavity.

### CROSS-REFERENCE TO RELATED APPLICATIONS

The present application claims the benefit and priority of CN Patent Application Serial No. 202510397547.8 filed on Mar. 31, 2025, and hereby incorporated fully by reference into the present application.

### TECHNICAL FIELD

This application relates to a circuit package structure, and more specifically, to a conductive pillar structure, a circuit package structure with a conductive pillars and a manufacturing method thereof.

### BACKGROUND OF THE INVENTION

To adapt to the rapid development of modern GPUs (graphics processing units) and CPUs (central processing units), the size of power converters needs to be correspondingly reduced while their power supply capacity needs to be enhanced. By arranging semiconductor power device chips, discrete components, inductive elements, and the conductive structures that connect them in a three-dimensional layout, it is possible to form a power converter module that is more highly integrated and easier for users to use.

Such power converter modules can have a more compact circuit packaging structure, which usually includes a device layer and an inductive component layer. It is necessary to improve the coupling stability between the device layer and the inductive component layer to ensure the reliability of the power converter module.

### BRIEF DESCRIPTION OF DRAWINGS

For a better understanding of the present disclosure, embodiments of the invention will be described in accordance with the following drawings, which are used for illustrative purposes only. The drawings illustrate only some of the features in an embodiment. It should be understood that the drawings are not necessarily to scale. Like elements are provided with like reference numerals in different appended drawings.

FIG. 1A is a schematic diagram of a circuit package structure 100 according to an embodiment of the present application.

FIG. 1B is a perspective view of a circuit package structure 100 according to an embodiment of the present application.

FIG. 1C shows a schematic cross-sectional view along the dashed line AA′ of the circuit package structure 100 of FIG. 1A according to an embodiment of the present invention.

FIG. 2 shows a common coupling failure situation.

FIG. 3A-FIG. 3J illustrate some exemplary embodiments of a conductive pillar 120 with a side wall having a cavity for encapsulant material.

FIG. 4 shows an embodiment of the conductive pillar 120 provided with a first accommodating structure for a first coupling material.

### DETAILED DESCRIPTION OF THE INVENTION

Detailed description of the embodiments is provided merely to give examples and not intended to be limiting. Plenty of details are provided to assist the reader in gaining a comprehensive understanding of the present invention. However, many other ways of implementing the disclosure of this application described herein will be apparent. Description of materials and methods that are known in the art may not be addressed in this disclosure for simplicity.

Throughout the specification and claims, the articles “a,” “an,” and “the” are intended to include the plural forms as well, unless the context clearly indicates otherwise. These phrases “one embodiment”, “an embodiment”, “an example” and “examples” are not necessarily directed to the same embodiment or example. Furthermore, the features, structures, or characteristics may be combined in one or more embodiments or examples.

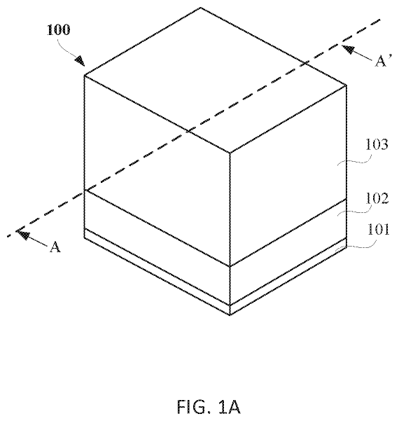

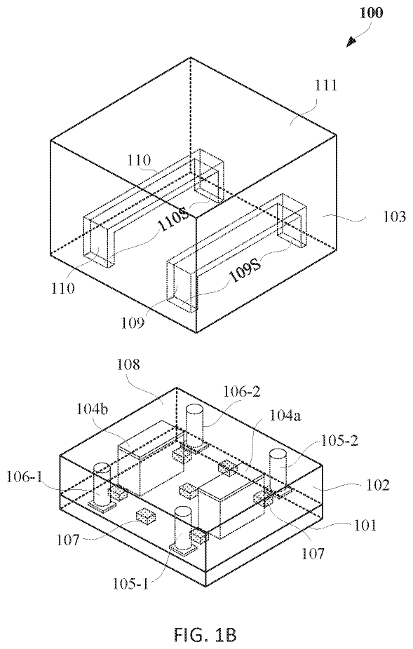

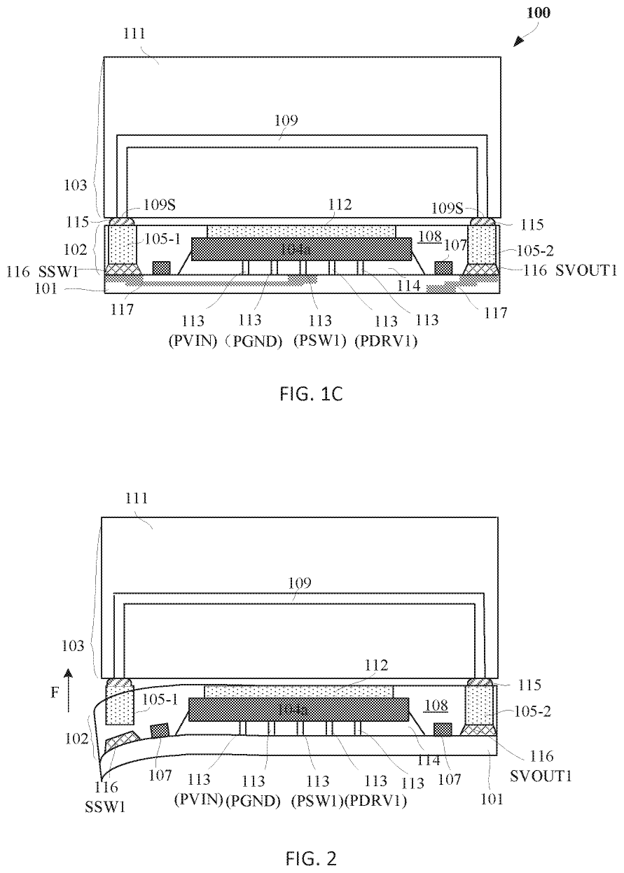

FIG. 1A illustrates a schematic diagram of a circuit packaging structure 100 according to an embodiment of the present disclosure. The circuit packaging structure 100 includes a device layer 102 and an inductive component layer 103. The device layer 102 typically includes semiconductor power device chips, discrete devices, and conductive structures that make up the power conversion circuit. The inductive component layer 103 is located at the top of the circuit packaging structure 100 and includes inductive components that make up the power conversion circuit. In some embodiments, a bottom layer 101 is located at the bottom of the circuit packaging structure 100 and mainly serves a supporting function; for example, it may include a PCB substrate.

FIG. 1B illustrates a perspective view of a circuit package structure 100 according to one embodiment of the present disclosure. As shown in FIG. 1B, the device layer 102 includes a first power device chip 104a, a second power device chip 104b, a first pair of conductive pillars 105-1 and 105-2, a second pair of conductive pillars 106-1 and 106-2, and multiple discrete devices 107. An encapsulating material 108 encapsulates these components and isolates them from each other. The end surfaces of some of these components, such as a top surface of each of the conductive pillars (105-1, 105-2, 106-1 and 106-2) is not covered by the encapsulating material 108 to facilitate external electrical connections. In one embodiment, the first power device chip 104a and the second power device chip 104b may be power chips that integrate multiple switching transistors, drivers, and other auxiliary circuits. In FIG. 1B, conductive pillars 105-1 and 105-2 are arranged on opposite sides of the first power device chip 104a, and conductive pillars 106-1 and 106-2 are located on opposite sides of the second power device chip 104b. However, in other embodiments, the positions of these conductive posts can be adjusted according to the structure and location of other components of the circuit package 100. The discrete devices 107 may include components such as resistors and capacitors that make up the power conversion circuit, for example, those capacitors used as input capacitors or filter capacitors.

As shown in FIG. 1B, the inductive component layer 103 mainly includes a magnetic core material 111, as well as a first winding 109 and a second winding 110 embedded in the magnetic core material 111. A surface of the magnetic core material 111 constitutes a surface of the inductive component layer 103. The first winding 109 and the magnetic core material 111 correspond to the first inductive component L1, and the second winding 110 and the magnetic core material 111 correspond to the second inductive component L2. The magnetic core material 111 may be common magnetic core materials such as ferrite or metal alloy cores. To provide the first winding 109 and the second winding 110, common winding materials such as metallic copper or metallic aluminum may be used. In the embodiment shown in FIG. 1B, multiple surfaces of the first winding 109 and the second winding 110 are covered by the magnetic core material 111, with only the bottom end faces 109S and 110S exposed from the magnetic core material 111 to serve as terminals for external electrical connections. However, in other embodiments, other surfaces of the first winding 109 and the second winding 110 may also be configured to be exposed from the magnetic core material 111. In the embodiment shown in FIG. 1B, the first winding 109 and the second winding 110 are illustrated to have an inverted ‘U’ shape, however, in other embodiments, the windings may have other shapes. In addition, in other embodiments, the inductive element layer 103 may also include a heat sink embedded in the magnetic core material 111 to enhance heat dissipation.

FIG. 1C shows a schematic cross-sectional view along the dashed line AA′ of the circuit package structure 100 of FIG. 1A according to an embodiment of the present invention. As illustrated in FIG. 1C, the first power device chip 104a has a first surface and a second surface opposite to it. A heat dissipation layer 112 for assisting heat dissipation is disposed on the first surface, while the second surface has multiple pins 113, such as an input pin PVIN for receiving input voltage, a ground pin PGND, a switch pin PSW1 coupled to the power transistor, a drive pin PDRV1 coupled to the driver, etc. Those skilled in this art should understand that the pins shown in FIG. 1C are provided for illustrative purposes only and do not limit the scope of the invention. In practical applications, each power device chip may have more pins. Furthermore, the size and positional distribution of the pins may vary in different applications. The first power device chip 104a is coupled to the bottom layer 101 through multiple pins 113, thereby coupling key nodes of the integrated circuit within the first power device chip 104a to the electrical connection structure 117 within the bottom layer 101 through the multiple pins, forming an electrical path connected to external circuits, devices, or components. The bottom layer 101 may be placed on a motherboard where a load (such as a CPU, GPU, etc.) is located, and other circuits, devices, or components can be set on the motherboard to provide input voltage, switch control signals, and reference voltage. The filling material 114 is arranged between the second surface of the first power device chip 104a and the bottom layer 101, surrounding multiple pins 113 and isolating them from each other. As shown in FIG. 1C, the first winding 109 is embedded within the magnetic core material 111 and is illustrated in an inverted ‘U’-shaped structure, with its bottom end face 109S exposed from the lower surface of the magnetic core material 111. The exposed end face 109S is electrically connected to the first pair of conductive pillars 105-1 and 105-2 embedded in the device layer 102 by welding, soldering or other similar methods. In the example of FIG. 1C, the exposed end face 109S of the first winding 109 is coupled to a first coupling material 115 (for example, solder) and further coupled to the first pair of conductive pillars 105-1 and 105-2 embedded in the device layer 102. The top surfaces of the first pair of conductive pillars 105-1 and 105-2 are exposed from the upper surface of the device layer 102 and are coupled to the end face 109S of the first winding 109. The bottom surfaces of the first pair of conductive pillars 105-1 and 105-2 are electrically connected to the surface of the bottom layer 101 by soldering or other similar methods, thereby establishing an electrical connection with the electrical connection structure 117 of the bottom layer 101. In the example of FIG. 1C, the bottom surfaces of the first pair of conductive pillars 105-1 and 105-2 are coupled to the bottom layer 101 via a second coupling material 116 (for example, solder). In the example of FIG. 1C, the coupling point formed by connecting the bottom surface of the conductive pillar 105-1 and the second coupling material 116 serves as a first switch terminal SSW1 of the power conversion circuit and, through the electrical connection structure 117 of the bottom layer 101, is electrically connected to a switch pin PSW1 of the first power device chip 104a. Thus, the first power device chip 104a is further electrically coupled to the first winding 109 through the conductive posts 105-1. The coupling point forming by connecting the bottom surface of the conductive pillar 105-2 to the second coupling material 116 serves as a first output voltage terminal SVOUT1 of the power conversion circuit and is coupled to the bottom layer 101.

As mentioned above, the bottom layer 101 serves as a carrier and in some embodiments, it may be a PCB. The bottom layer 101 may include a multilayer structure composed of a base material and deposited thin film materials (such as oxides, nitrides, metal layers, etc.). Due to differences in the thermal expansion coefficients and stress between the base material and the deposited thin film materials, the bottom layer 101 may suffer from warpage issue during use. Furthermore, the device layer 102 includes the encapsulating material 108 and power device chips and conductive pillars embedded in the encapsulating material 108. Due to differences in thermal expansion coefficients and stress of these components, the device layer 102 may also experience a certain degree of warpage during use. The main body of the inductive element layer 103 is composed of a magnetic core material 111 made of common magnetic core materials such as ferrite or metal alloy cores, and common winding materials such as metal copper or metal aluminum. There are significant differences in thermal expansion coefficients and stress between the inductive element layer 103, the bottom layer 101 and device layer 102, which may cause coupling failures during use. Generally, due to the difference in the coefficients of thermal expansion between the bottom layer 101 and the device layer 102, during the heating and cooling process in daily use, the combined body of the bottom layer 101 and the device layer 102 may warp. FIG. 2 shows a common type of coupling failure. As shown in FIG. 2, the conductive pillars 105-1 embedded in the encapsulating material 108 is lifted by an upward force (illustrated as “F” in FIG. 2), causing the coupling between these conductive pillars 105-1 and the second coupling material 116 to be broken. If such a coupling failure occurs in the aforementioned example, it will result in the electrical connection between the first switch terminal SSW1 and the switch pin PSW1 of the first power device chip 104a being disconnected, directly causing the power conversion circuit to fail to operate. Those skilled in the art should understand that FIG. 2 merely illustrates one possible coupling failure scenario. However, because the coupling between the side wall of the conductive pillar and the encapsulating material 108 is too weak to resist forces in the direction parallel to the extension direction of the conductive pillar (illustrated as “F” in FIG. 2), any external force along the extension direction of the conductive pillar may trigger a coupling failure.

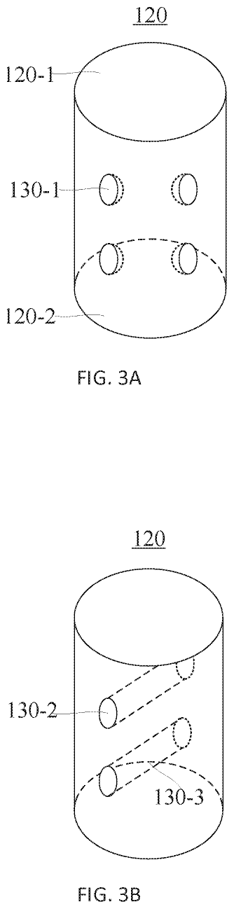

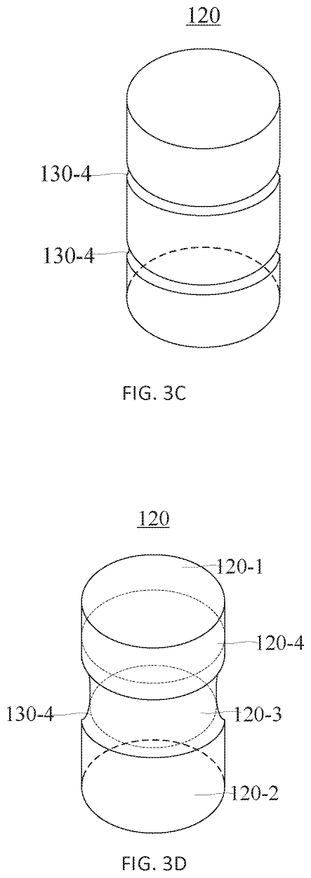

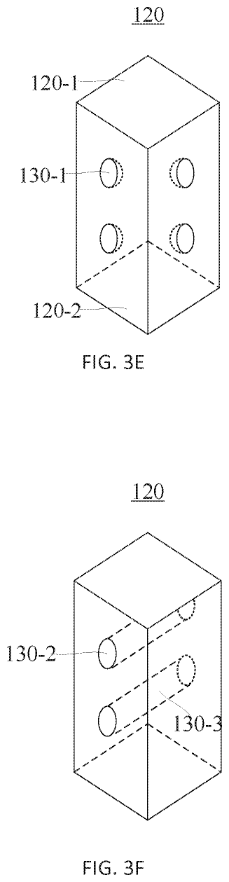

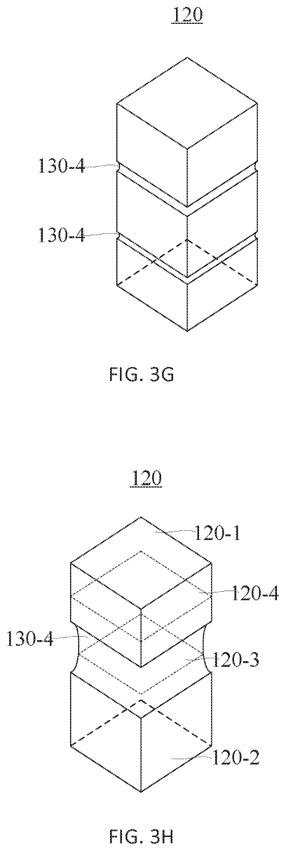

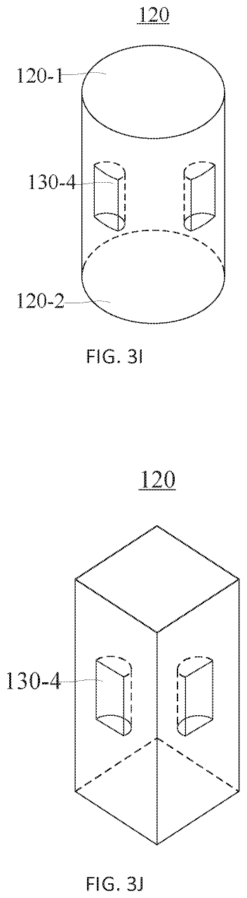

To address the aforementioned issues, a conductive pillar 120 with a cavity 130 for accommodating the encapsulating material 108 is proposed in the present disclosure, which can be used to replace the first pair of conductive pillars (105-1 and 105-2) and the second pair of conductive pillars (106-1 and 106-2) in the circuit package structure 100. The conductive pillar 120 has two end surfaces, a top surface 120-1 and a bottom surface 120-2. The conductive pillar 120 may be configured to be embedded into the encapsulating material 108 with its top surface 120-1 exposed from the encapsulating material 108. The bottom surface 120-2 may be configured to be coupled to the bottom layer 101 through soldering or other similar means, and the top surface 120-1 may be configured to be coupled to the inductive element layer 103 through soldering or other similar means. Thus, the conductive pillar 120 establishes electrical and mechanical connections between the bottom layer 101 and the inductive element layer 103. The side wall of the conductive pillar 120 is provided with cavity 130 (for example, those schematic structures labeled 130-1 to 130-4 in FIG. 3A-3J) for accommodating the encapsulating material 108. In some embodiments, at a part of the side wall where the cavity 130 is provided, a cross-section 120-3 of the conductive pillar 120 can be obtained by cutting along a plane parallel to the top surface 120-1 (for simplicity, the cross-section 120-3 is only shown in FIG. 3D and FIG. 3H). In other part of the side wall of the conductive pillar 120 where the cavity 130 is not provided, at least one cross-section 120-4 of the conductive pillar 120 can be obtained by cutting along a plane parallel to the top surface 120-1 (for simplicity, the cross-section 120-4 is only shown in FIG. 3D and FIG. 3H). The area of the cross-section 120-3 which is obtained at the position where the cavity 130 is provided by cutting the conductive pillar 120 along a plane parallel to the top surface 120-1 is smaller than the area of the cross-section 120-4. In some embodiments, at the cavity 130, a cross-section 120-3 of the conductive pillar 120 obtained by cutting along a plane parallel to the top surface 120-1 (for simplicity, only this cross-section 120-3 is shown in FIG. 3D and FIG. 3H). At a part of the conductive pillar 120 where the cavity 130 is provided, the area of the cross-section 120-3 of the conductive pillar 120 obtained by cutting along a plane parallel to the top surface 120-1 is smaller than the area of the top surface 120-1, and/or the area of the cross-section 120-3 is smaller than the area of the bottom surface 120-2. When the encapsulating material 108 is filled around the conductive pillar 120 during the manufacture process of the circuit package structure 100, the encapsulating material 108, which still has a certain fluidity, is filled into the cavity 130. After the curing process, the encapsulating material 108 filled around the conductive pillar 120, together with the portion of the encapsulating material which filled into the cavity 130, is cured into a single integral piece. The portion of the encapsulating material that filled into the cavity 130 is fixed in the space of cavity 130, thus the conductive pillar 120 and the encapsulating material 108 form an interlocked structure, which will help improve the stability of the coupling between the conductive pillar 120 and the encapsulating material 108.

FIG. 3A to FIG. 3J show some exemplary embodiments of the conductive pillars 120 whose side wall includes the cavity 130 for accommodating the encapsulation material 108. Although FIG. 1B and FIG. 1C schematically depict the first pair of conductive pillars (105-1 and 105-2) and the second pair of conductive pillars (106-1 and 106-2) as cylindrical, they can also be cuboid as shown in FIG. 3E to FIG. 3H. Those skilled in the art should understand that the conductive pillar 120 can also have other suitable shapes. As shown in FIG. 3A and FIG. 3E, a dimple or a blind hole 130-1 is provided on the side wall of the conductive pillar 120. When the encapsulating material 108 is provided in the manufacturing process, the conductive pillar 120 as shown in FIG. 3A or FIG. 3E is embedded into the encapsulating material 108, the uncured encapsulating material 108 can fill into the dimple or blind hole 130-1. After the curing process, the encapsulating material 108 surrounding the conductive pillar 120 and the encapsulating material 108 that filled into the dimple or blind hole 130-1 are cured into a single integral piece. The portion of the encapsulating material 108 filled into the dimple or blind hole 130-1 is fixed in the space of the dimple or blind hole 130-1. When an upward force is applied to the conductive pillar 120, due to the presence of the encapsulating material 108 which fixed in the dimple or blind hole 130-1, the encapsulating material 108 is more firmly locked with the conductive pillar 120, which helps the conductive pillar 120 resist the upward force and prevents it from being pulled upward. Referring to FIG. 3B and FIG. 3F, the cavity 130 may be in a form of a through hole 130-2. The through hole 130-2 penetrates the conductive pillar 120 with its two end surfaces exposed from the side wall of the conductive pillar 120. When the conductive pillar 120 as shown in FIG. 3B or FIG. 3F is embedded into uncured encapsulating material 108, the uncured encapsulating material 108 can fill into the through hole 130-3. After the curing process, the encapsulating material 108 surrounding the conductive pillar 120 and the encapsulating material 108 filled into the through hole 130-3 are cured into a single integral piece. The portion of the encapsulating material filled into the through hole 130-3 is fixed in the through hole 130-3 after curing. Referring to FIGS. 3C, 3D, 3G, and 3H, the cavity 130 may be in a form of a groove. One or more grooves 130-4 are provided on the side wall of the conductive pillar 120. When the conductive pillar 120, as shown in FIGS. 3C, 3D, 3G, and 3H, is surrounded by uncured encapsulating material 108, the uncured encapsulating material 108 can fill into one or more grooves 130-4. After the curing process, the encapsulating material 108 surrounding the conductive pillar 120 and the portion filled into the one or more grooves 130-4 are cured into a single integral piece, and the portion of the encapsulating material filled into the one or more grooves 130-4 is fixed in the one or more grooves 130-4.

Although in these schematic diagrams, groove 130-4 is exemplarily illustrated as encircling the side wall of conductive pillar 120 with a uniform depth and shape, those skilled in the art should understand that groove 130-4 can also be set with a non-uniform depth or shape, or arranged in a manner that does not completely encircle the sidewall of conductive pillar 120. Although in FIGS. 3C, 3D, 3G, and 3H, the extending direction of groove 130-4 is exemplarily illustrated as being along the perimeter direction around the side wall of conductive pillar 120, it is also possible to set groove 130-4 to extend in other directions. For example, as shown in FIGS. 3I and 3J, the extending direction of groove 130-4 is parallel to the extending direction of conductive pillar 120.

In one embodiment of the present application, the cavity 130 for accommodating the encapsulation material 108 can be formed on the conductive pillar 120 through an etching process. Taking FIG. 3E as an example, a patterned photoresist layer can be formed on the side wall of the conductive pillar 120, followed by etching to remove part of the material of the conductive pillar 120, thereby forming the dimple or blind hole 130-1. In another embodiment of the present application, the cavity 130 can be formed on the conductive pillar 120 through a cutting process, for example, laser cutting, wire cutting, etc. Taking FIG. 3G as an example, the side wall of the conductive pillar 120 can be cut to remove part of the material of the conductive pillar 120, thereby forming the groove 130-4.

In addition, it is worth noting that although in the perspective view of the circuit package structure 100 in FIG. 1B, the positions of the first pair of conductive pillars (105-1 and 105-2) are schematically shown on both sides of the first power device chip 104a, the positions of the second pair of conductive pillars (106-1 and 106-2) are schematically shown on both sides of the second power device chip 104b, and the first winding 109 and the second winding 110 are schematically shown as an inverted “U” shape, all of these illustrations and descriptions do not constitute a limitation on the application environment of the conductive pillar 120 described in this disclosure.

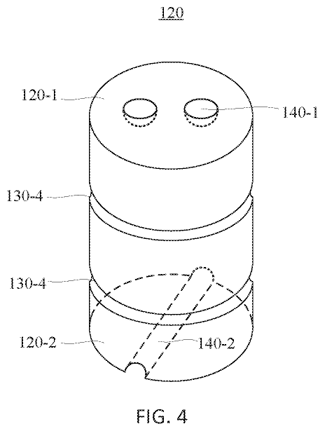

With reference to FIG. 4, in one embodiment of the present disclosure, the top surface 120-1 of the conductive pillar 120 is provided with a first accommodating structure 140-1 and/or the bottom surface 120-2 of the conductive pillar 120 is provided with a second accommodating structure 140-2. The first accommodating structure 140-1 is provided for receiving the first coupling material 115 used to couple the top surface 120-1 of the conductive pillar 120 to the inductive element layer 103. The second accommodating structure 140-2 is provided for receiving the second coupling material 116 used to couple the bottom surface 120-2 of the conductive pillar 120 to the bottom layer 101. In the example of FIG. 4, a dimple or blind hole 140-1 is provided on the top surface 120-1 of the conductive pillar 120, and a groove 140-2 is provided on the bottom surface 120-2 of the conductive pillar 120. The illustrated dimple or blind hole 140-1 and the groove 140-2 are merely some possible specific embodiments of the first/second accommodating structure.

When the conductive pillar 120 of FIG. 4 is used to replace the first pair of conductive pillar (105-1 and 105-2) and the second pair of conductive pillar (106-1 and 106-2) in the circuit package structure 100, the uncured first coupling material 115 can fill into the space of the first accommodating structure 140-1 on the top surface 120-1, and/or the uncured second coupling material 116 can fill into the space of the second accommodating structure 140-2 on the bottom surface 120-2. After the first coupling material 115 and/or the second coupling material 116 are cured, the conductive pillar 120 and them form an interlocking structure, which will help to further improve the stability of the circuit package structure 100.

Although the present invention has been described with reference to several typical embodiments, it should be understood that the terms used are illustrative and exemplary rather than restrictive. Since the invention can be embodied in various forms without departing from the spirit or essence of the invention, it should be understood that the above embodiments are not limited to any of the foregoing details, but should be construed broadly within the spirit and scope defined by the appended claims, and therefore all changes and modifications falling within the scope of the claims or their equivalents should be covered by the appended claims.

1. A circuit package structure with conductive pillar, comprising:
a device layer, wherein a conductive pillar and a semiconductor power device chip embedded in an encapsulating material are disposed in the device layer;
a top surface of the conductive pillar is exposed from the encapsulating material and coupled to a first coupling material, and a bottom surface of the conductive pillar is coupled to a second coupling material;
an inductive element layer disposed on the device layer, wherein the inductive element layer includes a magnetic core material and a winding embedded in the magnetic core material, and end surfaces of the winding are exposed from the magnetic core material and coupled to the first coupling material;
a side wall of the conductive pillar is provided with a cavity for containing the encapsulating material, and the encapsulating material is filled in the cavity.

2. The circuit package structure of claim 1, at a part of the side wall of the conductive pillar that is not provided with the cavity, at least one cross section obtained by cutting the conductive pillar along a plane parallel to the top surface is a first cross section; at the part of the side wall of the conductive pillar where the cavity is disposed, a cross section obtained by cutting the conductive pillar along a plane parallel to the top surface is a second cross section, and an area of the second cross section is less than an area of the first cross section.

3. The circuit package structure of claim 1, at a part of the side wall of the conductive pillar that provided with the cavity, an area of a cross section obtained by cutting the conductive pillar along a plane parallel to the top surface is less than an area of the top surface, and/or less than an area of the bottom surface.

4. The circuit package structure of claim 1, wherein the cavity is in a form of a dimple or a blind hole.

5. The circuit package structure of claim 1, wherein the cavity is in a form of a through hole penetrating through the conductive pillar, and each end surface of the through hole is exposed from the side wall of the conductive pillar.

6. The circuit package structure of claim 1, wherein the cavity is in a form of a groove.

7. The circuit package structure of claim 1, wherein the top surface of the conductive pillar includes a first accommodating structure for the first coupling material and/or the bottom surface of the conductive pillar includes a second accommodating structure for the second coupling material.

8. The circuit package structure of claim 1, the circuit package structure further includes a bottom layer with an electrical connection structure, wherein the electrical connection structure is coupled to the bottom surface of the conductive pillar.

9. A conductive pillar for a circuit package structure, comprising:
a top surface and a bottom surface, wherein the conductive pillar is adapted to be embedded in an encapsulating material with the top surface of the conductive pillar exposed from the encapsulating material;
a cavity for accommodating the encapsulating material disposed on a part of a side wall of the conductive pillar;
wherein at a part of the side wall of the conductive pillar that is not provided with the cavity, at least one cross section obtained by cutting the conductive pillar along a plane parallel to the top surface is a first cross section; at the part of the side wall of the conductive pillar where the cavity is disposed, a cross section obtained by cutting the conductive pillar along a plane parallel to the top surface is a second cross section, and an area of the second cross section is less than an area of the first cross section.

10. The conductive pillar of claim 9, wherein the cavity is in a form of a dimple or a blind hole.

11. The conductive pillar of claim 9, wherein the cavity is in a form of a through hole penetrating through the conductive pillar, and each end surface of the through hole is exposed from the side wall of the conductive pillar.

12. The conductive pillar of claim 9, wherein the cavity is in a form of a groove.

13. The circuit package structure of claim 9, wherein the top surface of the conductive pillar includes a first accommodating structure for the first coupling material.

14. The circuit package structure of claim 9, wherein the bottom surface of the conductive pillar includes a second accommodating structure for the second coupling material.

15. A conductive pillar for a circuit package structure, comprising:
a top surface and a bottom surface, wherein the conductive pillar is adapted to be embedded in an encapsulating material with the top surface of the conductive pillar exposed from the encapsulating material;
a cavity for accommodating the encapsulating material, provided at a part of a side wall of the conductive pillar;
wherein at a part of the side wall of the conductive pillar that provided with the cavity, an area of a cross section obtained by cutting the conductive pillar along a plane parallel to the top surface is less than an area of the top surface, and/or less than an area of the bottom surface.

16. The conductive pillar of claim 15, wherein the cavity is in a form of a dimple or a blind hole.

17. The conductive pillar of claim 15, wherein the cavity is in a form of a through hole penetrating through the conductive pillar, and each end surface of the through hole is exposed from the side wall of the conductive pillar.

18. The conductive pillar of claim 15, wherein the cavity is in a form of a groove.

19. The circuit package structure of claim 15, wherein the top surface of the conductive pillar includes a first accommodating structure for the first coupling material.

20. The circuit package structure of claim 15, wherein the bottom surface of the conductive pillar includes a second accommodating structure for the second coupling material.
